(19) United States
(12) Patent Application Publication
(10) Pub. No.: US 2007/0000868 A1
(43) Pub. Date: Jan. 4, 2007

(54) Dry etching method

(75) Inventor: Takayuki Sakai, Tokyo (JP)

Correspondence Address: C. IRVIN MCCLELLAND;OBLON, SPIVAK, MCCLELLAND, MAIER & NEUSTADT, P.C., 1940 DUKE STREET, ALEXANDRIA, VA, 22314, US

(73) Assignee: Kabushiki Kaisha Toshiba, Minato-ku (JP)

(21) Appl. No.: 11/476,094

(22) Filed: Jun. 28, 2006

(30) Foreign Application Priority Data
Jun. 29, 2005 (JP) 2005-190691

(51) Int. Cl. C03C 25/68; H01L 21/461; H01L 21/302; B44C 1/22; C23F 1/00

(52) U.S. Cl. 216/67; 216/58; 438/706; 438/710

(57) ABSTRACT

A dry etching method comprises: exposing an etching region of a workpiece to a plasma product of a depositive gas, the depositive gas having a CF group in a reaction chamber; exposing the etching region to a plasma product of an etching gas in the reaction chamber; exposing the etching region to a plasma product of the depositive gas in the reaction chamber; and exposing the etching region to a plasma product of the etching gas in the reaction chamber. Alternatively, a dry etching method comprises: exposing an etching region of a workpiece to a plasma product of a depositive gas, the depositive gas containing a fluorocarbon-based gas and at least one of CO (carbon monoxide) gas, hydrogen gas, and CH₄ gas in a reaction chamber; exposing the etching region to a plasma product of an etching gas in the reaction chamber; exposing the etching region to a plasma product of the depositive gas in the reaction chamber; and exposing the etching region to a plasma product of the etching gas in the reaction chamber.

### CROSS-REFERENCE TO RELATED APPLICATION

This application is based upon and claims the benefit of priority from the prior Japanese Patent Application No. 2005-190691, filed on Jun. 29, 2005; the entire contents of which are incorporated herein by reference.

### BACKGROUND OF THE INVENTION

1. Field of the Invention

This invention relates to a dry etching method, and more particularly to a method of dry etching a workpiece such as a semiconductor substrate using a plasma source, for example.

2. Background Art

The dry etching technique is widely used in manufacturing semiconductor devices. This technique is also important in the fields of MEMS (Micro Electro Mechanical System) and micromachining based on semiconductor substrates. In these fields, a technique is needed for forming a deep hole or groove (hereinafter referred to as “trench”) vertical to the surface of a silicon (hereinafter denoted as Si) substrate. For example, it may be necessary to form in a Si substrate a vertical trench with a width of several micrometers and a depth of several tens of micrometers, or a vertical through-hole in the depth direction with a width of 100 μm or more.

In a previously disclosed dry etching method for forming a trench (see, e.g., JP 2004-327606A, pp. 3-4, FIG. 1), an apparatus having a plasma generating source is used to vertically etch a semiconductor substrate by alternately switching between an etching gas SF₆ (sulfur hexafluoride) and a depositive gas C₄F₈ (cyclobutane octafluoride), that is, by alternately repeating the step of forming a trench by etching (etching step) and the step of forming a sidewall protection film for the etched trench (deposition step). On the sidewall of the trench formed below a resist mask, a discontinuous surface feature, that is, an undulation of irregularities is observed, which corresponds to the repetition of the etching step and the deposition step.

This disclosed proposal does not show a method of increasing the etching rate. It is contemplated that in order to increase the etching rate, for example, the etching gas flow rate can be increased to raise the F (fluorine) radical supply rate and the reaction product removal rate.

However, in the case where the etching gas flow rate is increased, the pressure regulation valve cannot follow the gas switching due to a large difference of gas flow rate relative to the alternately switched depositive gas. This results in a pressure variation and makes the plasma unstable. For the purpose of avoiding the plasma instability, if the C₄F₈ gas flow rate during the deposition step is increased in an attempt to reduce the pressure variation at the time of switching between the etching step and the deposition step, there arises a problem that it is difficult to suitably control the processed feature of the trench sidewall.

### SUMMARY OF THE INVENTION

According to an aspect of the invention, there is provided a dry etching method comprising a plurality of iterations of: exposing a surface of a workpiece to a decomposed product of a depositive gas, the depositive gas having a CF group; and exposing the surface of the workpiece to a decomposed product of an etching gas.

According to other aspect of the invention, there is provided a dry etching method comprising: exposing an etching region of a workpiece to a plasma product of a depositive gas, the depositive gas having a CF group in a reaction chamber; exposing the etching region to a plasma product of an etching gas in the reaction chamber; exposing the etching region to a plasma product of the depositive gas in the reaction chamber; and exposing the etching region to a plasma product of the etching gas in the reaction chamber.

According to other aspect of the invention, there is provided a dry etching method comprising: exposing an etching region of a workpiece to a plasma product of a depositive gas, the depositive gas containing a fluorocarbon-based gas and at least one of CO (carbon monoxide) gas, hydrogen gas, and CH₄ gas in a reaction chamber; exposing the etching region to a plasma product of an etching gas in the reaction chamber; exposing the etching region to a plasma product of the depositive gas in the reaction chamber; and exposing the etching region to a plasma product of the etching gas in the reaction chamber.

### BRIEF DESCRIPTION OF THE DRAWINGS

FIG. 1 is a configuration diagram that schematically shows a dry etching apparatus for use in carrying out a dry etching method according to a first example of the invention.

FIG. 2 is a cross section that schematically shows the shape of a trench formed by the dry etching method according to the first example of the invention and the resulting amount of undercut on the sidewall.

FIG. 3 shows the amount of undercut versus the flow rate of the depositive gas used in the dry etching method according to the first example of the invention.

FIG. 4 shows the etching rate versus the flow rate of the etching gas used in the dry etching method according to the first example of the invention.

FIG. 5 is a schematic diagram showing the molecular structure of C₄F₈.

FIG. 6 is a schematic diagram showing the molecular structure of C₅F₈.

FIG. 7 shows the amount of undercut for the flow rate of the depositive gas used in a dry etching method according to a second example of the invention.

FIG. 8 is a schematic diagram showing the molecular structure of C₄F₆.

FIG. 9 is a configuration diagram that schematically shows a dry etching apparatus for use in carrying out a dry etching method according to a third example of the invention.

FIG. 10 shows the amount of undercut for the flow rate of CO gas added as a depositive gas in the dry etching method according to the third example of the invention.

### DETAILED DESCRIPTION OF THE INVENTION

Embodiments of the invention will now be described with reference to the drawings. In the figures referred to below, like elements are marked with like reference numerals. The embodiments of the invention will now be described in more detail with reference to examples.

### First Example

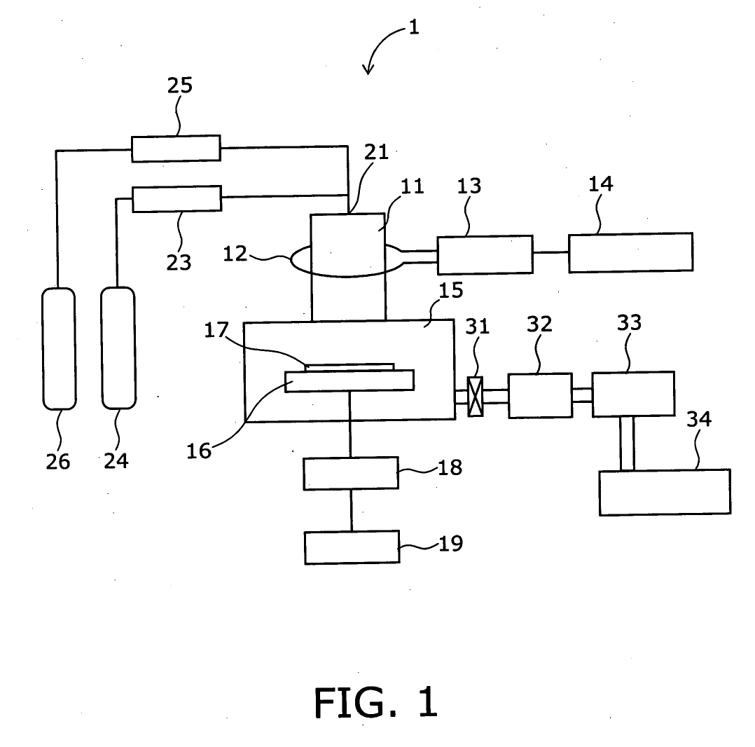

A dry etching method according to a first example of the invention is described with reference to FIGS. 1 to 4.

FIG. 1 is a configuration diagram that schematically shows a dry etching apparatus for use in dry etching a workpiece.

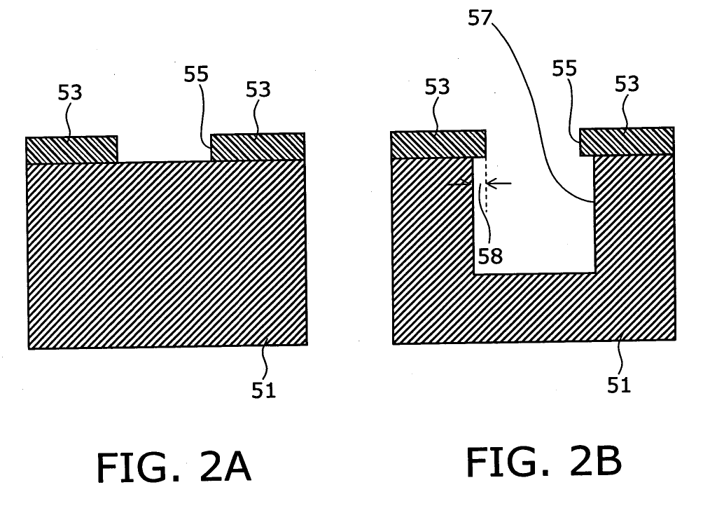

FIG. 2A is a schematic cross section of a Si substrate before dry etching, and FIG. 2B is a cross section that schematically shows the shape of a trench formed by the dry etching method and the resulting amount of undercut on the sidewall.

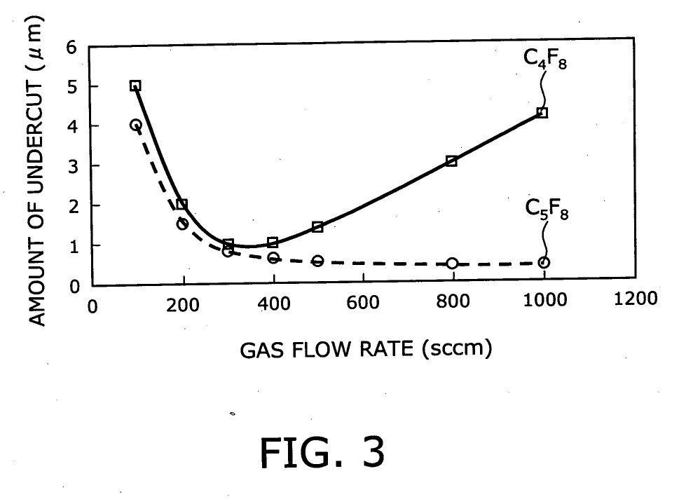

FIG. 3 shows the amount of undercut versus the depositive gas flow rate.

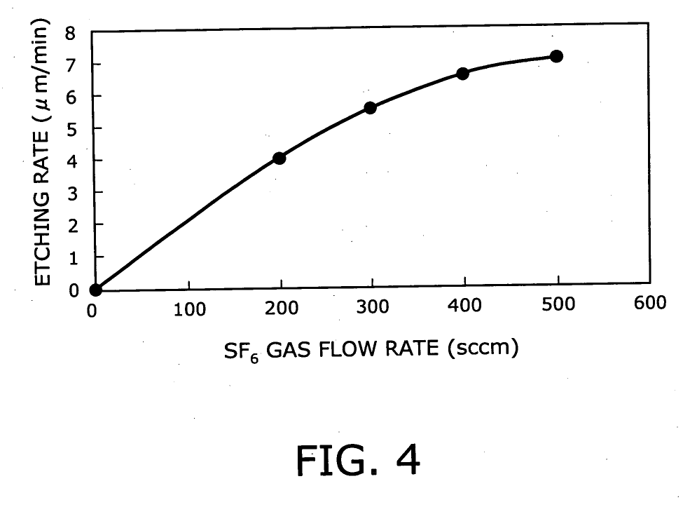

FIG. 4 shows the etching rate versus the etching gas flow rate.

As shown in FIG. 1, a dry etching apparatus 1, which illustratively has an inductively coupled plasma (ICP) source, comprises a plasma generating chamber 11 and a reaction chamber 15 connected to the plasma generating chamber 11. An antenna 12 for supplying radio-frequency energy to the plasma generating chamber 11 is installed on the periphery of the plasma generating chamber 11. A radio-frequency power supply 14 is connected to the antenna 12 via a matching circuit 13. The reaction chamber 15 contains a lower electrode 16 on which a workpiece 17 is mounted. A radio-frequency power supply 19 is connected to the lower electrode 16 via a matching circuit 18. Note that the plasma generating chamber 11 does not necessarily need to be sharply distinguished from the reaction chamber 15. The inductively coupled plasma source is a system that can generate a high-density plasma (with a plasma density of about 10¹¹ to 10¹³ cm⁻³).

The dry etching apparatus 1 has a gas inlet 21 on top of the plasma generating chamber 11. The supply sources of an etching gas (gas having an etching property) 24 and a depositive gas 26 are connected to the gas inlet 21 via, for example, flow rate controllers 23 and 25 including mass flow controllers (MFC), respectively. A turbo molecular pump 32 is connected to the reaction chamber 15 via a pressure regulating valve 31. A dry pump 33 is connected to the exhaust side of the turbo molecular pump 32. The exhaust side of the dry pump 33 is in turn connected to an emission treatment system 34, the exhaust side of which is connected to an exhaust duct (not shown). The valve 31, turbo molecular pump 32, dry pump 33, emission treatment system 34, and exhaust duct constitute an exhaust system.

The flow of gases in the dry etching apparatus 1 is described. The flow rate of SF₆ (sulfur hexafluoride), which is the etching gas 24, and C₅F₈ (perfluorocyclopentene), which is the depositive gas 26 having a CF group, stored in respective cylinders, is controlled by the flow rate controllers 23 and 25, and these gases are fed into the plasma generating chamber 11. A high-density plasma generated from SF₆ or C₅F₈ in the plasma generating chamber 11 produces plasma products such as radicals and decomposition products, which are moved toward the workpiece 17 under the action of the lower electrode 16 or the exhaust system for processing the workpiece 17 in the reaction chamber 15. The plasma products then come into contact and react with the workpiece 17. The reacted gas or unreacted gas in the reaction chamber 15 is exhausted by the turbo molecular pump 32 to the dry pump 33 side. Note that Ar (argon) gas (not shown), for example, may be simultaneously fed into the plasma generating chamber 11 for plasma generation.

Note that the term “CF group” as used in this specification means CF₁, and thus, it does not include such as CF₂ and CF₃.

The dry etching apparatus 1 having the above configuration was used to investigate conditions for the dry etching method. In order to form a desired trench feature in a Si substrate serving as the workpiece 17, a resist mask 53 having an opening 55 in an etching region of the surface of the Si substrate 51 was formed as shown in FIG. 2A.

In the reaction chamber of the dry etching apparatus 1, the Si substrate 51 was mounted at the position of the workpiece 17 shown in FIG. 1. In the first and third steps of forming a protection film (the deposition steps), the radio-frequency power supplied to the antenna 12 is 1000 W, the pressure in the reaction chamber 15 is 50 mTorr (6.7 Pa), and the supply power to the lower electrode is 0 W. The flow rate of the depositive C₅F₈ gas is a variable parameter. Thus, an surface of the Si substrate 51 is exposed to a decomposed product a depositive gas having a CF group.

In the second and fourth steps of etching (the etching steps), the radio-frequency power supplied to the antenna 12 is 2500 W, the SF₆ gas flow rate is 1 slm (1000 sccm), the pressure in the reaction chamber 15 is 90 mTorr (12 Pa), and the supply power to the lower electrode is 50 W. Thus, an surface of the Si substrate 51 is exposed to a decomposed product a etching gas. The SF₆ gas flow rate was set after the etching rate (not shown) was confirmed up to 1.2 slm.

Under this condition, a plurality of cycles are repeated to etch the Si substrate 51 depending on the desired trench depth and the like, where one cycle is defined as a combination of the deposition step (e.g., about 1 to 2 seconds) and the etching step (e.g., about 2 to 5 seconds). Thus, as shown in FIG. 2B, a trench 57 is formed vertically to the Si substrate 51.

As shown in FIG. 2B, as etching proceeds in the depth direction of the trench 57, that is, vertically to the Si substrate 51, etching also occurs in the direction vertical to the sidewall. The difference between the edge of the opening 55 of the resist mask 53 extended in the depth direction and the sidewall of the trench 57 is defined as the amount of undercut 58 and used for characterizing the feature of the trench 57. The sidewall 57 has a microscopic undulation of irregularities, but it is small as compared to the amount of undercut and therefore depicted by a straight line in the figure.

FIG. 3 shows the C₅F₈ gas flow rate dependence of the amount of undercut 58. For comparison, FIG. 3 also shows the result of forming a trench by feeding the dry etching apparatus 1 with the conventionally used C₄F₈ (cyclobutane octafluoride) gas instead of C₅F₈ used in this example.

As shown in FIG. 3, the horizontal axis represents the depositive gas flow rate (sccm), and the vertical axis represents the amount of undercut (μm). For C₅F₈, plotted by circles and a dashed line, the amount of undercut monotonically decreases with the increase of the gas flow rate. The amount of undercut does not increase even when the flow rate is increased up to 1 slm. The amount of undercut is about 0.4 μm when the C₅F₈ gas flow rate is 1 slm. On the other hand, for the conventional C₄F₈ gas, plotted by squares and a solid line, the amount of undercut decreases with the increase of the gas flow rate from 100 sccm, is minimized at 300 to 400 sccm, and tends to increase with a further increase of the flow rate.

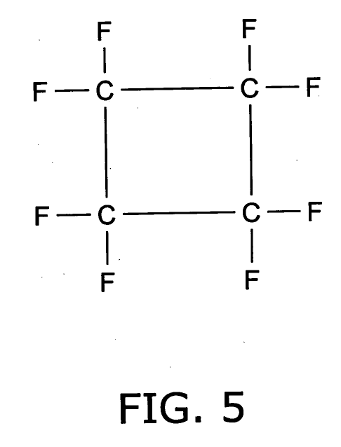

These results can be explained as follows by comparison with C₄F₈, which has a molecular structure shown in FIG. 5. In the case of C₄F₈, the increase of the gas flow rate leads to an increase of the amount of CF radicals suitable for forming a protection film, and to an increase of the amount of deposition onto the sidewall of the trench 57, thereby enhancing the effect of reducing the amount of undercut. A further increase of the gas flow rate with the pressure in the reaction chamber 15 kept constant results in a decreased residence time of the gas in the reaction chamber 15, which allows only the C-C bonding to dissociate and does not advance C-F dissociation (see FIG. 5). Then CF radicals suitable for forming a protection film decrease, and CF₂ radicals unsuitable for forming a protection film increases. As a result, the amount of deposition of protection film onto the sidewall of the trench 57 decreases, and the amount of undercut begins to increase again.

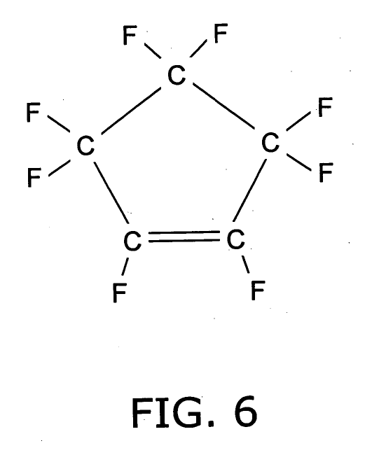

On the other hand, C₅F₈ in this example dissociates in a different manner due to its different molecular structure, which presumably results in a different trench feature. More specifically, as shown in FIG. 6, C₅F₈ has CF₂ and CF groups at a ratio of 3:2, and thus is likely to produce CF radicals. For this reason, the increase of the C₅F₈ gas flow rate initially leads to a rapid increase of the amount of CF radicals as with C₄F₈, thereby enhancing the effect of protecting the sidewall of the trench 57. A further increase of the gas flow rate with the pressure in the reaction chamber 15 kept constant results in a decreased residence time in the plasma. However, even in this situation, the amount of CF radicals suitable for forming a protection film on the sidewall does not decrease, but presumably continues a slight increase. As a result, the amount of undercut is kept as low as about 0.4 μm even when the C₅F₈ gas flow rate is 1 slm.

As described above, according to this example, cyclic C₅F₈ having a CF group can be used as a depositive gas to reduce the amount of undercut relative to conventional techniques even when the C₅F₈ gas flow rate is increased to about 1 slm. However, the well-known etching gas SF₆ tends to increase the etching rate with the increase of its flow rate.

FIG. 4 is a graphical diagram showing an example of the etching rate of the Si substrate versus the SF₆ gas flow rate. It can be seen from FIG. 4 that in the etching step, the etching rate increases as the SF₆ gas flow rate increases. Hence, the gas flow rates of the etching gas and the depositive gas can be set to increased values (e.g., about 800 to 1000 sccm) while maintaining the gas flow rate difference enough to prevent the plasma from being unstable at the time of switching these gases. Thus, by alternately switching these gases, the etching rate for trench formation can be increased, and the amount of undercut can be reduced. That is, use of C₅F₈ allows for providing a method of increasing the etching rate while preventing the deterioration of the etched feature.

In addition, according to the dry etching method of this example, a deep trench vertical to the surface of the Si substrate can be formed while preventing the trench from expanding in the sidewall direction because the amount of undercut can be reduced. Therefore the present method can be applied more widely in the fields of semiconductor devices as well as MEMS and micromachining based on Si substrates.

### Second Example

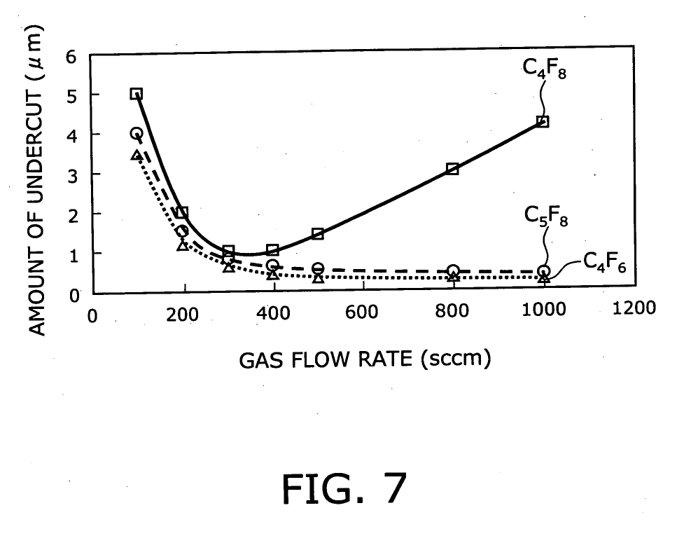

A dry etching method according to a second example of the invention is described with reference to FIG. 7.

FIG. 7 shows the amount of undercut versus the depositive gas flow rate. This example is different from the first example in using C₄F₆ as a depositive gas. In the following, elements identical or corresponding to those in the first example are marked with like reference numerals and not described in detail, and different elements are described.

The dry etching apparatus used in this example has the same configuration as that of the first example except that the depositive gas 26 shown in FIG. 1 is C₄F₆ (hexafluorocyclobutene). The elements such as the radio-frequency power, the pressure in the reaction chamber 15, and the Si substrate 51 are the same as those of the first example.

FIG. 7 shows the amount of undercut 58 versus the C₄F₆ gas flow rate so as to be compared with C₅F₈ used in the first example and C₄F₈ used conventionally. The horizontal and vertical axes are the same as in FIG. 3.

As shown in FIG. 7, for C₄F₆, plotted by triangles and a dotted line, the amount of undercut monotonically decreases with the increase of the gas flow rate. The amount of undercut does not increase even when the flow rate is increased up to 1 μm. The amount of undercut is about 0.3 μm when the C₄F₆ gas flow rate is 1 slm. In comparison with the amount of undercut for C₅F₈ used in the first example, the amount of undercut for C₄F₆ used in this example shows nearly the same trend, which is slightly lower.

This can be explained by the molecular structure of C₄F₆ used in this example.

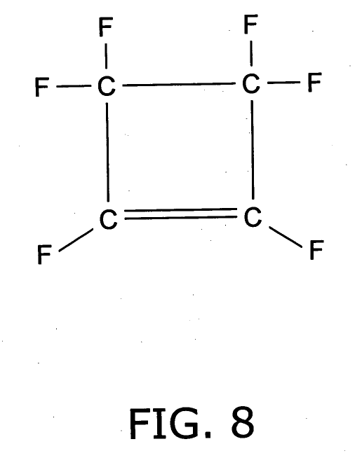

As shown in FIG. 8, C₄F₆ has CF₂ and CF groups at a ratio of 1:1, and thus is likely to produce CF radicals. For this reason, the increase of the C₄F₆ gas flow rate leads to a rapid increase of the amount of CF radicals, thereby enhancing the effect of protecting the sidewall of the trench. A further increase of the gas flow rate with the pressure in the reaction chamber 15 kept constant results in a decreased residence time in the plasma. However, even in this situation, the amount of CF radicals suitable for forming a protection film on the sidewall does not decrease, but presumably continues a slight increase. As a result, the amount of undercut is kept as low as about 0.3 μm even when the C₄F₆ gas flow rate is 1 slm. The amount of undercut being lower than that for C₅F₈ used in the first example can presumably be attributed to the higher ratio of CF groups for C₄F₆.

As described above, according to this example, cyclic C₄F₆ having a CF group can be used as a depositive gas to achieve the same effect as the first example. In addition, the amount of undercut can be further reduced.

### Third Example

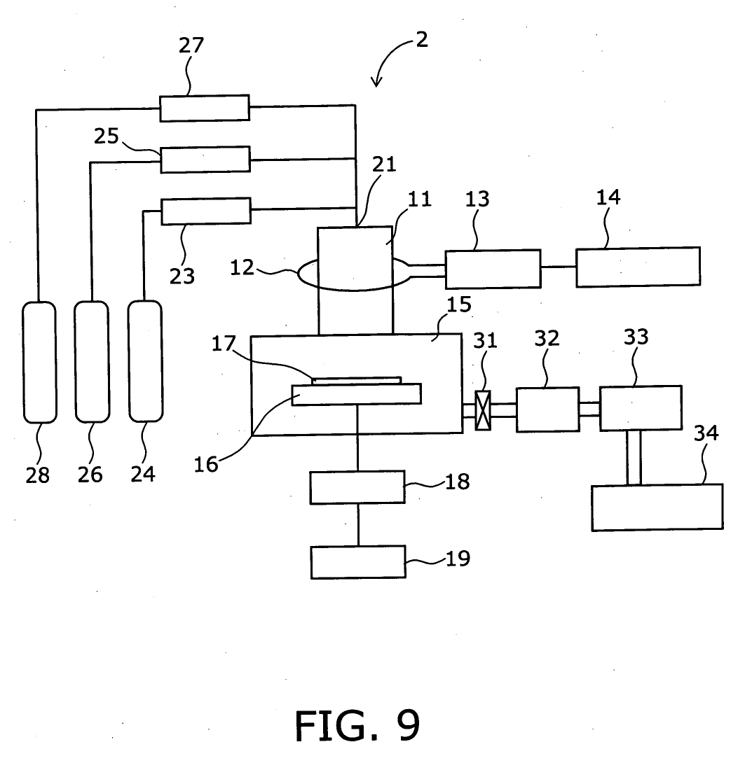

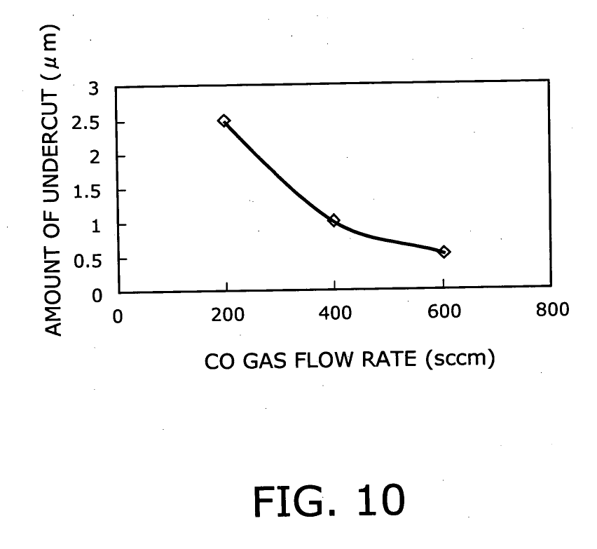

A dry etching method according to a third example of the invention is described with reference to FIGS. 9 and 10. FIG. 9 is a configuration diagram that schematically shows a dry etching apparatus for use in dry etching a Si substrate, and FIG. 10 shows the amount of undercut versus the flow rate of CO gas added as a depositive gas. This example is different from the first example in using C₄F₈ and additionally CO gas as depositive gases. In the following, elements identical or corresponding to those in the first example are marked with like reference numerals and not described in detail, and different elements are described.

As shown in FIG. 9, the dry etching apparatus 2 has a supply system for CO (carbon monoxide) gas 28 in addition to the dry etching apparatus 1 of the first example. The CO gas 28 stored in a cylinder is fed via a flow rate controller 27 into the gas inlet 21 on top of the plasma generating chamber 11. The depositive gas 26 stored in another cylinder is C₄F₈.

The elements of the dry etching apparatus 2 such as the radio-frequency power, the pressure in the reaction chamber 15, and the Si substrate 51 for examining the amount of undercut are the same as those of the first example. In the first and third steps of forming a protection film (the deposition steps) using the dry etching apparatus 2, the gas flow rate of C₄F₈, which is a cyclic fluorocarbon-based gas, is 800 sccm, and CO gas is added. The second and fourth steps of etching (the etching steps) are the same as in the first example. The Si substrate 51 is etched to form a trench 57 therein as in FIG. 2B.

The C₄F₈ gas flow rate is fixed to 800 sccm (see FIG. 3). In FIG. 10, the horizontal axis represents the CO gas flow rate (sccm), and the vertical axis represents the amount of undercut (μm). As shown in FIG. 10, the amount of undercut monotonically decreases with the increase of the added CO gas flow rate from 200 to 600 sccm. The amount of undercut is about 0.5 μm when the CO gas flow rate is 600 sccm. In contrast, without CO gas flow, as shown in FIG. 3, the amount of undercut is about 3 μm when the C₄F₈ gas flow rate is 800 sccm. Thus the amount of undercut is reduced by adding CO gas.

This result can be explained as follows in comparison with the case of using only C₄F₈ as in conventional techniques. Because of the dissociation to CF₂ groups, the flow of C₄F₈ at a flow rate of 800 sccm relatively decreases the ratio of CF groups suitable for forming a protection film on the sidewall. However, the addition of CO gas allows C atoms suitable for forming a protection film to be dissociated from CO in the plasma, and thereby increasing the C/F ratio on the Si substrate surface. This presumably facilitates the formation of a protection film on the sidewall of the trench 57 and decreases the amount of undercut.

As described above, according to this example, cyclic C₄F₈ having no CF group in its molecular structure can be used simultaneously with CO gas to reduce the amount of undercut relative to conventional techniques even when the C₄F₈ gas flow rate is increased to about 800 sccm. However, the etching gas tends to increase the etching rate with the increase of its flow rate. Hence, the etching rate can be increased, and the amount of undercut can be reduced, by alternately switching the deposition step and the etching step while maintaining the gas flow rate difference enough to prevent the plasma from being unstable at the time of switching between the etching gas and the depositive gas containing additional CO gas. That is, use of C₄F₈ with additional CO gas allows for providing a method of increasing the etching rate while preventing the deterioration of the etched feature.

Note that the same effect can also be achieved by adding hydrogen (H₂), for example, instead of CO gas. More specifically, as described above, the decomposition of C₄F₈ produces CF₂. If hydrogen is added to this reaction, fluorine (F) in CF₂ reacts with hydrogen to produce CF suitable for forming a protection film on the sidewall. As a result, the effect of protecting the trench sidewall is enhanced, and the amount of undercut can be reduced even when the etching rate is increased.

The same effect can also be achieved by adding CH₄ instead of CO gas. More specifically, the decomposition of CH₄ in a plasma produces C and H. The generated C atoms contribute to forming a protection film on the sidewall. The generated hydrogen reacts with CF₂ generated by the decomposition of C₄F₈ to produce CF suitable for forming a protection film on the sidewall. As a result, the effect of protecting the trench sidewall is enhanced, and the amount of undercut can be reduced even when the etching rate is increased.

The dry etching method of this example can use C₄F₈ gas, which has conventionally been mass-produced. Thus the cost of trench formation can be reduced. Therefore the present method can be applied more widely in the fields of semiconductor devices as well as MEMS and micromachining based on Si substrates.

The invention is not limited to the examples described above, but can be variously modified without departing from the spirit and scope of the invention.

For example, while C₅F₈ and C₄F₆ are used as depositive gases in the first and second examples, other fluorocarbon-based compounds having a CF group in the molecular structure can also achieve a similar effect, and can be alternatively used as a depositive gas.

While C₄F₈ and CO are illustratively used as a primary gas and an additional gas of the depositive gas in the third example, other fluorocarbon-based compounds having a CF₂ group, or C₅F₈, C₄F₆, or the like having a CF group can be used as a primary gas of the depositive gas in combination with CO used as an additional gas.

In the above examples, where a trench is formed in the Si substrate serving as a workpiece, the surface of the Si substrate may be provided with a polysilicon film, silicide film, dielectric film, SiGe, or the like. The workpiece may also be a compound semiconductor substrate.

In the above examples, an apparatus having an inductively coupled plasma (ICP) source is illustratively used as a dry etching apparatus. However, the plasma source may be other plasma sources capable of generating a high-density plasma, such as an electron cyclotron resonance plasma, helicon wave excited plasma, and microwave excited surface wave plasma.

1. A dry etching method comprising a plurality of iterations of:
exposing an surface of a workpiece to a decomposed product of a depositive gas, the depositive gas having a CF group; and
exposing the surface of the workpiece to a decomposed product of an etching gas.

2. A dry etching method according to claim 1, wherein the depositive gas is cyclic C₅F₈ (perfluorocyclopentene).

3. A dry etching method according to claim 1, wherein the depositive gas is cyclic C₄F₆ (hexafluorocyclobutene).

4. A dry etching method according to claim 1, wherein the etching gas is SF₆.

5. A dry etching method according to claim 1, wherein a radio-frequency voltage is applied to an electrode, on the electrode the workpiece is placed.

6. A dry etching method comprising:
exposing an etching region of a workpiece to a plasma product of a depositive gas, the depositive gas having a CF group in a reaction chamber;
exposing the etching region to a plasma product of an etching gas in the reaction chamber;
exposing the etching region to a plasma product of the depositive gas in the reaction chamber; and
exposing the etching region to a plasma product of the etching gas in the reaction chamber.

7. A dry etching method according to claim 6, wherein the depositive gas is cyclic C₅F₈ (perfluorocyclopentene).

8. A dry etching method according to claim 6, wherein the depositive gas is cyclic C₄F₆ (hexafluorocyclobutene).

9. A dry etching method according to claim 6, wherein the etching gas is SF₆.

10. A dry etching method according to claim 6, wherein the difference between the flow rate of the depositive gas and the flow rate of the etching gas is within a range of not making the plasma unstable when the depositive gas and the etching gas are switched.

11. A dry etching method according to claim 6, wherein the flow rate of the depositive gas and the flow rate of the etching gas are both 800 sccm or more and 1000 sccm or less.

12. A dry etching method according to claim 6, wherein a radio-frequency voltage is applied to an electrode on which the workpiece is placed.

13. A dry etching method according to claim 6, wherein at least one of CO (carbon monoxide) gas, hydrogen gas, and CH₄ gas is added to the depositive gas.

14. A dry etching method according to claim 6, wherein the etching region is an opening of a mask formed on a surface of the workpiece.

15. A dry etching method comprising:
exposing an etching region of a workpiece to a plasma product of a depositive gas, the depositive gas containing a fluorocarbon-based gas and at least one of CO (carbon monoxide) gas, hydrogen gas, and CH₄ gas in a reaction chamber;
exposing the etching region to a plasma product of an etching gas in the reaction chamber;
exposing the etching region to a plasma product of the depositive gas in the reaction chamber; and
exposing the etching region to a plasma product of the etching gas in the reaction chamber.

16. A dry etching method according to claim 15, wherein the fluorocarbon-based gas does not include CF group.

17. A dry etching method according to claim 15, wherein the fluorocarbon-based gas is cyclic C₄F₈ (cyclobutane octafluoride).

18. A dry etching method according to claim 15, wherein the etching region is an opening of a mask formed on a surface of the workpiece.

19. A dry etching method according to claim 15, wherein the etching gas is SF₆.

20. A dry etching method according to claim 15, wherein the flow rate of the depositive gas and the flow rate of the etching gas are both 800 sccm or more and 1000 sccm or less.
